(19) United States
(12) Patent Application Publication
(10) Pub. No.: US 2024/0220701 A1
(43) Pub. Date: Jul. 4, 2024

(54) METHOD AND SYSTEM FOR DESIGNING CIRCUIT BASED ON REINFORCEMENT LEARNING

(71) Applicant: Samsung Electronics Co., Ltd., Suwon-si (KR)

(72) Inventors: Taehyun KIM, Suwon-si (KR); Hyunjoong KIM, Suwon-si (KR); Jichull JEONG, Suwon-si (KR); Euihyun CHEON, Suwon-si (KR)

(73) Assignee: Samsung Electronics Co., Ltd., Suwon-si (KR)

(21) Appl. No.: 18/533,798

(22) Filed: Dec. 8, 2023

(30) Foreign Application Priority Data
Dec. 29, 2022 (KR) 10-2022-0189748

(51) Int. Cl. G06F 30/392; G06N 20/00

(52) U.S. Cl. CPC G06F 30/392; G06N 20/00

(57) ABSTRACT

Disclosed is a method and system for designing a circuit. The method of designing a circuit based on reinforcement learning may include obtaining a state variable of the reinforcement learning, obtaining output data by performing a simulation based on the state variable, calculating a reward variable of the reinforcement learning based on the output data, obtaining an action variable from an agent based on the state variable and the reward variable, training the agent based on the state variable, the reward variable, and the action variable, and updating the state variable based on the action variable, wherein the calculating of the reward variable includes estimating a variation of the circuit based on the state variable, and calculating the reward variable based on the estimated variation.

### CROSS-REFERENCE TO RELATED APPLICATION

This application is based on and claims priority under 35 U.S.C. § 119 to Korean Patent Application No. 10-2022-0189748, filed on Dec. 29, 2022, in the Korean Intellectual Property Office, the disclosures of which are incorporated by reference herein in their entirety.

### BACKGROUND

The inventive concepts relate to a circuit design, and more particularly, to a method and system for designing a circuit based on reinforcement learning.

Integrated circuits manufactured by semiconductor processes may have high operation speeds, and accordingly, it is very important to ensure that the semiconductor processes have high reliability and yield. Various factors in the semiconductor process can cause variations in integrated circuits, and thus, the integrated circuits may be required to be robust and to conform to specifications despite the various factors in the semiconductor process.

### SUMMARY

The inventive concepts provide a method and system for designing an integrated circuit by considering variations caused in a semiconductor process based on reinforcement learning.

According to an aspect of the inventive concepts, there is provided a method of designing a circuit based on reinforcement learning, which includes generating output data by performing a simulation of the circuit based on a state variable of the reinforcement learning; determining a reward variable of the reinforcement learning based on the output data; obtaining an action variable, from a reinforcement learning agent, based on the state variable and the reward variable; training the reinforcement learning agent based on the state variable, the reward variable, and the action variable; and updating the state variable based on the action variable, wherein the determining of the reward variable includes estimating a variation of the circuit based on the state variable, and determining the reward variable based on the estimated variation.

According to an aspect of the inventive concepts, there is provided a system for designing a circuit based on reinforcement learning, which includes a non-transitory storage medium storing instructions to execute a process of performing the reinforcement learning; and at least one processor configured to, by executing the instructions obtain output data by performing a simulation based on a state variable of the reinforcement learning; determine a reward variable of the reinforcement learning based on the output data; obtain an action variable from a reinforcement learning agent based on the state variable and the reward variable; train the reinforcement learning agent based on the state variable, the reward variable, and the action variable; and update the state variable based on the action variable, and wherein the determining of the reward variable includes estimating a variation of a circuit based on the state variable; and determining the reward variable based on the estimated variation.

According to an aspect of the inventive concepts, there is provided a non-transitory storage medium storing instructions, which when executed by at least one processor, cause the at least one processor to execute a process of performing reinforcement learning, the process of performing the reinforcement learning comprises: generating output data by performing a simulation based on a state variable of the reinforcement learning; determining a reward variable of the reinforcement learning based on the output data; obtaining an action variable from a reinforcement learning agent based on the state variable and the reward variable; training the reinforcement learning agent based on the state variable, the reward variable, and the action variable; and updating the state variable based on the action variable, wherein the determining of the reward variable comprises estimating a variation of a circuit based on the state variable, and determining the reward variable based on the estimated variation.

### BRIEF DESCRIPTION OF THE DRAWINGS

Embodiments of the inventive concepts will be more clearly understood from the following detailed description taken in conjunction with the accompanying drawings in which:

FIG. 1A is a block diagram of a reinforcement learning model according to at least one embodiment;

FIG. 1B is a block diagram showing updating variables of a reinforcement learning model according to at least one embodiment;

FIG. 2 is a block diagram of an agent of a reinforcement learning model according to at least one embodiment;

FIG. 3 is a block diagram of an environment of a reinforcement learning model according to at least one embodiment;

FIG. 4A is a circuit diagram of a sense amplifier circuit of a simulation device, according to at least one embodiment;

FIG. 4B is a circuit diagram of a timing variation according to at least one embodiment of FIG. 4A;

FIG. 4C is a graph showing a comparison result regarding a value of V_BLB and discharge of V_BLT, according to at least one embodiment of FIG. 4A;

FIG. 5A is a circuit diagram a current mode logic (CML)-to-complementary metal-oxide semiconductor (CMOS) (C2C) circuit obtained by combining a CML circuit and a CMOS circuit of a simulation device according to at least one embodiment;

FIG. 5B is a timing diagram of skew and duty according to at least one embodiment of FIG. 5A;

FIG. 6 is a flowchart of a method of designing a circuit based on reinforcement learning, according to at least one embodiment;

FIG. 7 is a flowchart of a method of estimating a variation of a circuit in the method of designing a circuit based on reinforcement learning according to at least one embodiment;

FIG. 8 is a flowchart of a method of determining whether a termination condition is satisfied in the method of designing a circuit based on reinforcement learning, according to at least one embodiment;

FIG. 9 is a block diagram of a computer system according to at least one embodiment; and

FIG. 10 is a block diagram of a system according to at least one embodiment.

### DETAILED DESCRIPTION OF THE EMBODIMENTS

Hereinafter, embodiments of the disclosure are described below in detail with reference to the accompanying drawings. The same reference numerals are used for the same components in the drawings, and redundant descriptions thereof will be omitted.

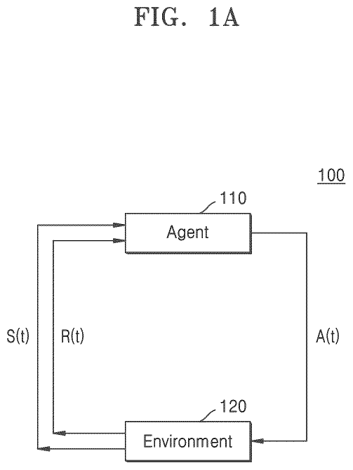

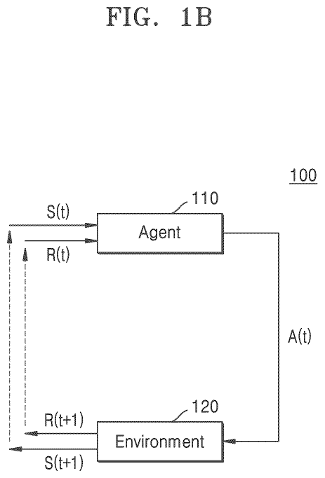

FIG. 1A is a block diagram of a reinforcement learning model 100 according to at least one embodiment. FIG. 1B is a block diagram showing updating variables of the reinforcement learning model 100.

The reinforcement learning model 100 may be used in circuit design based on reinforcement learning. Referring to FIG. 1A, the reinforcement learning model 100 may include an agent 110 and an environment 120. In the specification, the reinforcement learning model 100 may be referred to as a reinforcement learning platform, the agent 110 may be referred to as an agent module or a reinforcement learning agent, and the environment 120 may be referred to as an environment module or a reinforcement learning environment. Each of the agent 110 and the environment 120 may be implemented by hardware in a processor, and/or software executed on a processor. The reinforcement learning may refer to learning technique for selecting an optimal action for higher reward, by continuously and repeatedly reflecting a state and a reward that changes depending on an action that the agent 110 selects in the environment 120 that is given.

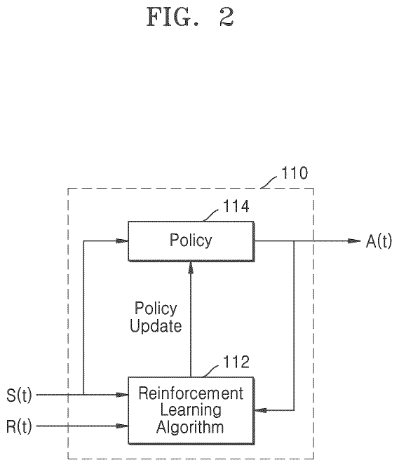

The agent 110, which is an object in which reinforcement learning is made, represents a subject or an object that acts in an environment. The environment 120 is a background interacting with the agent 110, and the reinforcement learning may refer to a process occurring through interaction between the agent 110 and the environment 120. The agent 110 may receive, from the environment 120, a state variable S(t) and a reward variable R(t), and provide an action variable A(t) to the environment 120. For example, the agent 110 may be trained to provide an action corresponding to the maximum reward in a state received from the environment 120. The agent 110 may be trained through a policy update, and/or by updating a quality (Q)-table. For example, as described below in FIG. 2, training may be made by updating a policy in the agent 110 by designating a specific time point while repeating the reinforcement learning. In at least some examples, the agent 110 may include a Q-table, and may be trained by updating the Q-table based on the reward variable R(t) received from the environment 120. The Q-table may include a Q-value including a reward variable for each of combinations of state variables and action variables. Referring to FIG. 1B, the environment 120 may change the state variable S(t) by the action variable A(t), and generate a reward variable R(t+1) based on the changed state variable S(t+1).

The state variable S(t) may include an initial state variable and/or the first state variable to the t-th state variable, and the reward variable R(t) may include an initial reward variable and the first reward variable to the t-th reward variable. The action variable A(t) may include the first action variable to the t-th action variable. The state variable S(t), the reward variable R(t), and the action variable A(t) may also be referred to as a state, a reward, and an action, respectively. For example, the agent 110 may receive, from the environment 120, an initial state variable and an initial reward variable, and provide the first action variable to the environment 120. The agent 110 may perform reinforcement learning based on the initial state variable and the initial reward variable received from the environment 120. In at least some examples, the agent 110 is trained to provide the action variable A(t) corresponding to the maximum reward variable R(t) in the state variable S(t). The agent 110 may output a first action variable through the reinforcement learning. The environment 120 may change the initial state variable to a first state variable by receiving the first action variable, and generate a first reward variable based on the changed first state variable.

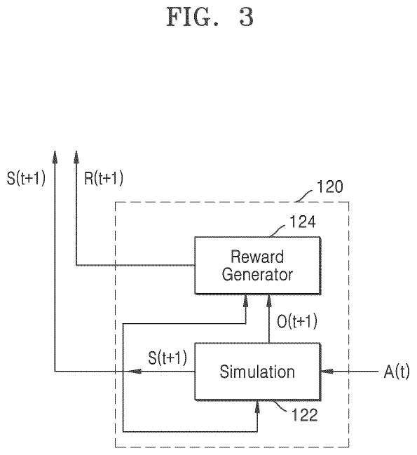

When receiving a current state variable S(t) and a current reward variable R(t) from the environment 120, the agent 110 is configured to determine the action variable A(t) according to the policy. The environment 120 may update the state variable S(t) to a next state variable S(t+1) according to the action variable A(t) determined by the agent 110, and determine a reward variable R(t+1) according to the updated state variable S(t+1). In some embodiments, the environment 120 may generate the first state variable and the first reward variable based on the detected initial state variable S(0) and initial reward variable R(0). Furthermore, the agent 110 may generate the action variable A(t) based on the state and reward provided from the environment 120. As described below with reference to the drawings, the reward variable R(t) of the reinforcement learning may be calculated by reflecting a variation, and thus, the agent 110 may be trained to design an optimal circuit reflecting the variation of a circuit in the reinforcement learning model 100. The operations of the agent 110 and the environment 120 are described below with reference to FIGS. 2 and 3.

FIG. 2 is a block diagram of the agent 110 of the reinforcement learning model 100 according to at least one embodiment.

As illustrated in FIG. 2, the agent 110 may include a reinforcement learning algorithm 112 and a policy 114.

The reinforcement learning algorithm 112 may be a model-free reinforcement learning algorithm or a model-based reinforcement learning algorithm. Furthermore, the reinforcement learning algorithm 112 may be a value-based reinforcement learning algorithm, such as a Q-table, or a policy-based reinforcement learning algorithm, such as policy optimization. The reinforcement learning algorithm 112 according to at least one embodiment may train the agent 110 in an appropriate direction through an appropriate update of the policy 114.

The policy 114 is configured to determine the action of the agent 110. The policy 114 may be trained towards policy optimization while taking an explicit policy, and/or may be trained based on the Q-table that is an action-value function while taking an implicit policy. The policy 114 may consist of deterministic values and/or stochastic values. Through the reinforcement learning according to at least one embodiment, the policy 114 may be optimized.

The agent 110 is configured to receive the state variable S(t) and the reward variable R(t), and the reinforcement learning algorithm 112 and the policy 114 may receive the state variable S(t) and the reward variable R(t). The reinforcement learning algorithm 112 may update the policy 114 at each specific time point, based on the received state variable S(t) and reward variable R(t), and the action variable A(t). A cycle to update the policy 114 may be updated for each repeated learning, and may be updated for each completion of one episode of reinforcement learning by performing repeated learning until an optimal value is found. The policy 114 may be cyclically updated, and may output the action variable A(t) according to the received state variable S(t) and reward variable R(t). When the policy 114 consists of deterministic values, the action variable A(t) may be determined according to an internal function, and when the policy 114 consists of stochastic values, the action variable A(t) may be stochastically selected with respect to the input state variable S(t). The output action variable A(t) may be provided to the environment 120.

FIG. 3 is a block diagram of the environment 120 of the reinforcement learning model 100 according to at least one embodiment.

As illustrated in FIG. 3, the environment 120 may include a circuit simulation 122 and a reward generator 124. The circuit simulation 122 may be a program (and/or a hardware/software combination) that simulates a circuit. The circuit simulation 122 may include data defining virtual structures, and is configured to generate simulated current-voltage properties and/or temperature properties by simulating a specific circuit in a device or a memory. The circuit simulation 122 may change the properties of an internal device or a transistor. For example, the properties change of a transistor may be a change of the width, length, material, and/or the like of a transistor device. The circuit simulation 122 may receive the state variable S(t), reflect the received state variable S(t) to a simulation, and output output data O(t). The output data O(t) may be a property to be optimized by the reinforcement learning model 100 including the circuit simulation 122. When an input to the circuit simulation 122 is the state variable S(t), the output data O(t) may be output. For example, when the state variable S(t) is the sizing of a transistor device (TR Sizing), the output data O(t) may be, for example, speed, power, area, yield, and/or the like, which are (or are related to) major specifications of a circuit. As an example, when the circuit includes a sense amplifier, the output data O(t) may be a sensing yield. As another example, when the circuit includes a current mode logic (CML)-to-complementary metal-oxide semiconductor (CMOS) (C2C) circuit, the output data O(t) may be skew or duty. When the action variable A(t) is input to the circuit simulation 122, the circuit simulation 122 may update the state variable S(t) to the state variable S(t+1) based on the action variable A(t). The updated state variable S(t+1) may be a new output value of the environment 120. The updated state variable S(t+1) may be input to the circuit simulation 122 and output data O(t+1) corresponding thereto may be output.

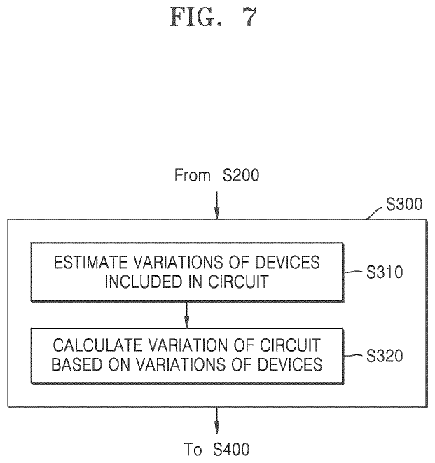

As the output data O(t) and the state variable S(t) are input to the reward generator 124, the reward generator 124 may generate the reward variable R(t) to be transmitted to the agent 110 based on the output data O(t). FIG. 3 is a block diagram according to at least one embodiment, and the reward generator 124 may generate the reward variable R(t) based on the state variable S(t) or the action variable A(t), or a combination thereof, except the output data O(t). The reward variable R(t) may be given as a reward value corresponding to one-time reinforcement learning, or a value obtained by progressively adding or reflecting rewards from the initial state to the current state may be given as a reward value. Although the reinforcement learning may be performed such that the reward variable R(t) and/or the sum of the reward variables R(t) amount to the maximum value, the disclosure is not limited to the maximum value only, and the reinforcement learning may be designed such that the reward variable R(t) and/or the sum of the reward variables R(t) amount to the minimum value and/or towards a specific value. The reward variable R(t) may be calculated by reflecting a value-function, which may be a state value-function or an action value-function. The reward variable R(t) may also be calculated or estimated by reflecting other variables. For example, the reward variable R(t) may be calculated based on the state variable S(t) and the output data O(t) that is a result value of the circuit simulation 122, and/or by reflecting a variation of a circuit to reflect variations of the circuit or other variables. Accordingly, properties sensitive to the variation may be optimized through the reinforcement learning. The variation of a circuit is described below in detail with reference to FIG. 7.

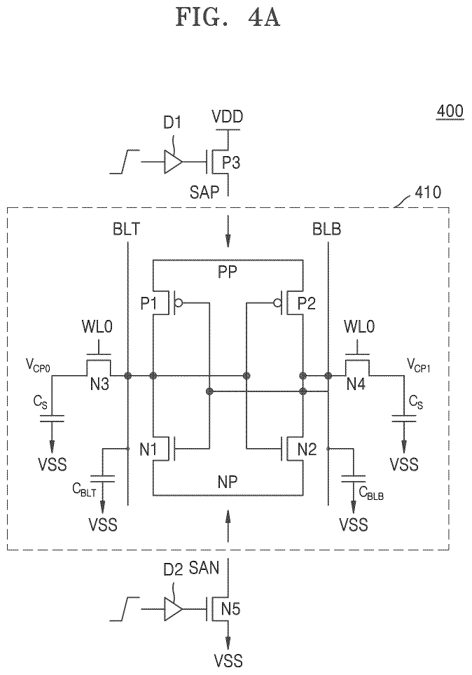

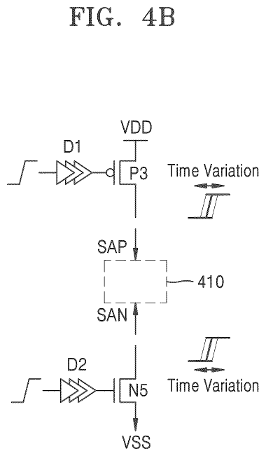

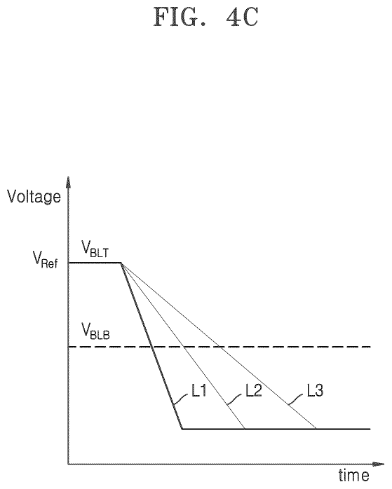

FIG. 4A is a circuit diagram of a sense amplifier 400 according to at least one embodiment. FIGS. 4B and 4C are views showing examples of a factor causing malfunction of the sense amplifier 400 of FIG. 4A, according to at least one embodiment.

Referring to FIG. 4A, the circuit simulation 122 is configured to simulate the sense amplifier 400. The sense amplifier 400 may sense a voltage difference, and may be used to read out data of a memory cell. The sense amplifier 400 may include a sensing circuit 410, and may include an amplifier for generating a sensing circuit control signal and a circuit including a transistor, which are connected to opposite ends of the sensing circuit 410. For example, a circuit for generating a positive control signal SAP to control a p-channel field effect transistor (PFET), for example, a sense amplifier P-FET control (SAP) signal, may be located above the sensing circuit 410 and connected to the sensing circuit 410, and the circuit may include a first amplifier D1 and a transistor P3. The first amplifier D1 may be connected to a gate of the transistor P3. A control signal may be applied to the first amplifier D1, and the control signal may be generated from a memory controller or host. A positive supply voltage VDD may be applied to one end of the transistor P3, and the other end thereof may be connected to the sensing circuit 410. The first amplifier D1 is configured to amplify the control signal and transmit the amplified control signal to the gate of the transistor P3. The gate of the transistor P3 is configured to be turned on or off in response to the signal received from the first amplifier D1. For example, the transistor P3 may be turned off in response to a control signal having a high level, and the transistor P3 may be turned on in response to a control signal having a low level. The transistor P3 may be a p-channel metal-oxide-semiconductor (PMOS) transistor.

A circuit for generating a negative control signal SAN to control an n-channel field effect transistor (NFET), for example, a sense amplifier N-FET control (SAN) signal, may be located below the sensing circuit 410 and connected to the sensing circuit 410, and the circuit may include a second amplifier D2 and a transistor N5. The second amplifier D2 may be connected to a gate of the transistor N5. A control signal may be applied to the second amplifier D2, and the control signal may be generated by the memory controller or host. A negative supply voltage VSS may be applied to one end of the transistor N5, and the other end thereof may be connected to the sensing circuit 410. The second amplifier D2 is configured to amplify the control signal and transmit the amplified control signal to the gate of the transistor N5. The gate of the transistor N5 is configured to be tuned on or off in response to the signal received from the second amplifier D2. For example, the transistor N5 may be turned on in response to a control signal having a high level, and the transistor N5 may be turned off in response to a control signal having a low level. The transistor N5 may be an NMOS transistor.

The sensing circuit 410 may include a plurality of transistors (e.g., N1 to N4, P1, and P2) and a plurality of capacitors (e.g., Cₛ, C_{BLT}, and C_{BLB}). The sensing circuit 410 may receive the negative control signal SAN to lower the voltage of a BLT bit line from a reference voltage V_ref to a ground voltage. Furthermore, the sensing circuit 410 may receive the positive control signal SAP to drive a BLB bit line to have a restored voltage value corresponding to digital value 1. The reference voltage V_ref may be a value corresponding to the half of the negative supply voltage VSS. The sensing circuit 410 may sense a fine voltage difference between the BLT bit line and the BLB bit line and amplify the difference. The sense amplifier 400 may malfunction due to the variations of devices, delays of signals, and/or the like. As an example, the sense amplifier 400 may malfunction due to a mismatch between the transistors P1 and P2, a mismatch between the transistors N1 and N2, different delays of signals, and/or the like. The examples of the factors causing the malfunction of the sense amplifier 400 are described below with reference to FIGS. 4B and 4C.

Referring to FIG. 4B, a positive control signal SAP generator above the sensing circuit 410 may generate the positive control signal SAP and apply the generated positive control signal SAP to the sensing circuit 410, and include the first amplifier D1 and the transistor P3. A negative control signal SAN generator below the sensing circuit 410 may generate the negative control signal SAN and apply the generated negative control signal SAN to the sensing circuit 410, and include the second amplifier D2 and transistor N5. As illustrated in FIG. 4B, a timing variation may occur in the positive control signal SAP and/or the negative control signal SAN, and thus, the sense amplifier 400 may malfunction.

Referring to FIG. 4C, a graph shows a voltage V_BLT of the BLT bit line and a voltage V_BLB of the BLB bit line of FIG. 4A. Referring to FIGS. 4A and 4B, the sensing circuit 410 may receive the negative control signal SAN and lower the voltage V_BLT of the BLT bit line from the reference voltage V_ref to the ground voltage. Due to the factors such as a variation of a capacitor device, a variation of wire resistance, and/or the like, a discharge speed of the voltage V_BLT of the BLT bit line may appear to be different, and thus, the sense amplifier 400 may malfunction.

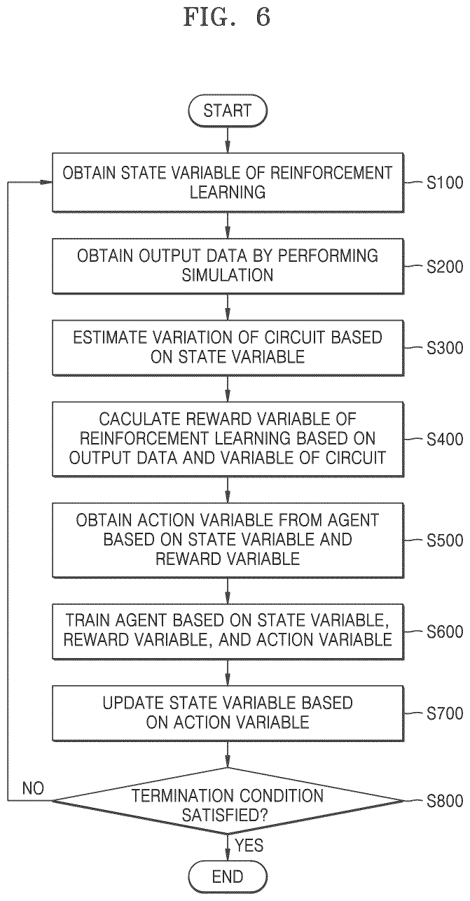

As described above, due to various factors, a variation may occur in the sense amplifier 400, and thus, the variation may decrease sensing yield. As described below with reference to FIG. 6 and the like, variation-based reinforcement learning may be employed and the circuit may be designed based on the reinforcement learning.

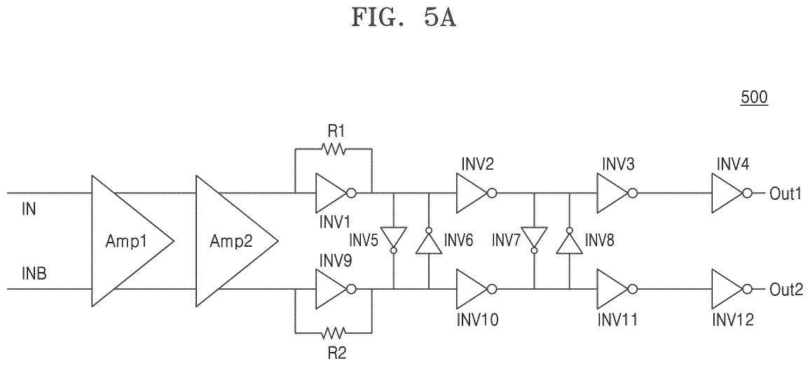

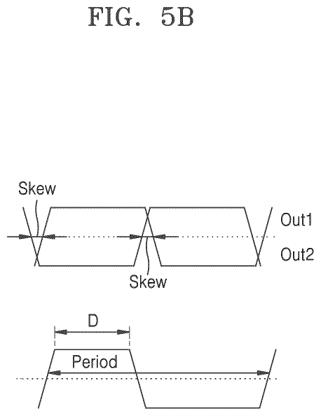

FIG. 5A is a circuit diagram of a C2C circuit 500 according to at least one embodiment, and FIG. 5B shows examples of factors causing the malfunction of the C2C circuit 500 of FIG. 5A, according to at least one embodiment.

Referring to FIG. 5A, the C2C circuit 500 may include a first amplifier Amp1, a second amplifier Amp2, and a plurality of inverters INV1 to INV12. The circuits included in the C2C circuit 500 may be classified into a current mode logic (CML) circuit and a complementary metal-oxide semiconductor (CMOS) circuit, depending on a signal processing method. For example, the first amplifier Amp1 and the second amplifier Amp2 may be CML circuits, and the first to twelfth inverters INV1 to INV12 may be CMOS circuits.

The first amplifier Amp1 is configured to receive a first input signal IN and a first inverted input signal INB. The second amplifier Amp2 is configured to receive signals output from the first amplifier Amp1. The first inverter INV1 and the ninth inverter INV9 may be connected to output terminals of the second amplifier Amp2. The first inverter INV1 and the ninth inverter INV9 are configured to receive, as an input, one of output signals of the second amplifier Amp2. The first inverter INV1 and the ninth inverter INV9 may be respectively connected in parallel to a first resistor R1 and a second resistor R2. The second inverter INV2 and the tenth inverter INV10 may be connected to output terminals of the first inverter INV1 and the ninth inverter INV9, respectively. The second inverter INV2 and the tenth inverter INV10 are configured to receive, as an input, output signals of the first inverter INV1 and the ninth inverter INV9, respectively. The third inverter INV3 and the eleventh inverter INV11 may be connected to output terminals of the second inverter INV2 and the tenth inverter INV10, respectively. The third inverter INV3 and the eleventh inverter INV11 may receive, as an input, output signals of the second inverter INV2 and the tenth inverter INV10, respectively. The fourth inverter INV4 and the twelfth inverter INV12 may be connected to output terminals of the third inverter INV3 and the eleventh inverter INV11, respectively. The fourth inverter INV4 and the twelfth inverter INV12 may receive, as an input, output signals of the third inverter INV3 and the eleventh inverter INV11. The fourth inverter INV4 and the twelfth inverter INV12 may output a first output signal Out1 and a second output signal Out2, respectively. A first duty variable Duty1 that is a ratio of a pulse width to a pulse cycle of the first output signal Out1, and a second duty variable Duty2 that is a ratio of a pulse width to a pulse cycle of the second output signal Out2, and a skew that is an arrival time difference between the first output signal Out1 and the second output signal Out2 may be calculated from the first output signal Out1 and the second output signal Out2.

The fifth inverter INV5 may be connected to the output terminal of the first inverter INV1, and a value output from the fifth inverter INV5 may be connected to an input terminal of the tenth inverter INV10. The sixth inverter INV6 may be connected to an output terminal of the ninth inverter INV9, and a value output from the sixth inverter INV6 may be connected to an input terminal of the second inverter INV2. The seventh inverter INV7 may be connected to an output terminal of the second inverter INV2, and a value output from the seventh inverter INV7 may be connected to an input terminal of the eleventh inverter INV11. The eighth inverter INV8 may be connected to an output terminal of the tenth inverter INV10, and a value output from the eighth inverter INV8 may be connected to an input terminal of the third inverter INV3.

Referring to FIG. 5B, the timing diagram shows skew and duty of the first output signal Out1 and the second output signal Out2 of FIG. 5A. In the C2C circuit 500 of FIG. 5A, when there is a variation between paths of differential signals, as illustrated in FIG. 5B, a skew that is an arrival time difference between the first output signal Out1 and the second output signal Out2 may occur. As such, the skew may be sensitive to the variation.

The duty may be represented as a duty ratio, a duty variable, duty value, or a duty cycle, which may be referred to as the same meaning in the specification. The duty may mean a ratio of time a signal is activated in one cycle of the signal, which is expressed as a percentage. Referring to FIG. 5B, the duty may be calculated as in Equation 1 below.

$$Duty Cycle = \frac{D}{Period} \qquad [ Equation 1 ]$$

From the first output signal Out1 and the second output signal Out2, an ideal duty value between the first duty variable Duty1 that is a ratio of a pulse width to a pulse cycle of the first output signal Out1, and the second duty variable Duty2 (e.g., a ratio of a pulse width to a pulse cycle of the second output signal Out2) may be 50%, but the duty value may vary depending on various variations, such as an actual process, a device properties difference, and the like, and thus, the duty may be sensitive to the variation. As described below with reference to FIG. 6 and the like, the variation-based reinforcement learning may be employed, and the circuit may be designed based on the reinforcement learning.

FIG. 6 is a flowchart of a method of designing a circuit based on reinforcement learning, according to at least one embodiment.

As illustrated in FIG. 6, the method of designing a circuit based on reinforcement learning may include a plurality of operations S100, S200, S300, S400, S500, S600, S700, and S800. FIG. 6 will be described below with reference to FIGS. 1 to 3.

Referring to FIG. 6, in operation S100, the reinforcement learning model 100 may obtain the state variable S(t) of reinforcement learning. For example, the state variable S(t) may be sizing of a transistor device. The state variable S(t) may be an initial state variable and/or a final state variable.

In operation S200, the circuit simulation 122 may obtain and/or generate the output data O(t) the output data O(t) by performing a simulation based on the state variable S(t). The circuit simulation 122 may include pieces of data that define virtual structures, and the circuit simulation 122 may output the output data O(t) by receiving the state variable S(t) and reflecting the received variable to the simulation. The output data O(t) may be a property that the reinforcement learning model 100 including the circuit simulation 122 desires to optimize. When the input of the circuit simulation 122 is the state variable S(t), the output data O(t) may be output.

In operation S300, the reinforcement learning model 100 may estimate a variation of a circuit based on the state variable S(t). Accordingly, the estimated variation of a circuit may be reflected in the calculation of the reward variable R(t) in operation S400 that is described later. The variation of a circuit may be based on variations of devices, or the arrangement, environment, and structure of the circuit. The variation of a circuit may be variations, such as performance, properties, yield, an output value, and the like. An example of the variation of a device, and a relationship between the variation of a device and the variation of a circuit, are described below in detail with reference to FIG. 7. For example, when the state variable S(t) includes an initial state variable, the reinforcement learning model 100 may estimate the changes in performance, properties, yield, output value, etc., based on the state variable S(t) and/or estimate the variations in the device structure in order to maintain prerequisites for the performance, properties, yield, output value, etc.; and/or when the state variable S(t) includes a final state variable, the reinforcement learning model 100 may estimate the variations in the device structure in order to match the final state variable.

In operation S400, the reward generator 124 may calculate the reward variable R(t) of the reinforcement learning based on the output data O(t) and the variation of a circuit. The reinforcement learning may be performed such that the reward variable R(t) is maximized, and to this end, a formula to calculate the reward variable R(t) may be established. In at least one example, e.g., wherein a decrease in the value of the output data O(t) is advantageous, the reinforcement learning may be set in a direction such that the value of the output data O(t) is multiplied by a negative (−) value, and/or the reward variable R(t) is minimized. When the output data O(t) is reflected to the reward variable R(t), only one value may be reflected, or a weighted sum of at least one value may be reflected. There is variability by the variations of devices and the variation of a circuit, and the variability, for example, a variation and/or the like, may occur in the output data O(t) and the like, the output data O(t) may be a target specification value. Considering the variability, a target value for circuit design may be set to be an average value μ of the specification value, or to be a weighted sum, e.g., μ+3σ, of the average value μ of the specification value and a standard deviation σ. Accordingly, by reflecting this, when calculating the reward variable R(t), the variation of a circuit may be reflected to the calculation. There may be various reflection methods, and as an example, the reward variable R(t) may be calculated by multiplying a standard deviation value of the circuit. Alternatively, the variation of a circuit may be reflected by differentiating the weight to which the standard deviation is multiplied, − or in the form of other four arithmetic operations such as dividing, or other functions, according to the characteristics of the variation. As a result of reflecting the variation of a circuit in the calculation of the reward variable R(t), the reinforcement learning may optimize not only the specification value itself, but also enable an optimized circuit design by reflecting the sensitivity to variation considering the variation, such as a variance and the like.

In operation S500, the environment 120 may obtain the action variable A(t) from the agent 110, based on the state variable S(t) and the reward variable R(t). As described above with reference to FIG. 2, the policy 114 of the agent 110 may determine the action variable A(t) to be output, based on the received state variable S(t) and reward variable R(t), and when the policy 114 consists of deterministic values, the action variable A(t) may be determined according to an internal function, and when the policy 114 consists of stochastic values, the action variable A(t) may be stochastically selected with respect to the received state variable S(t).

In operation S600, the reinforcement learning model 100 may train the agent 110 based on the state variable S(t), the reward variable R(t), and the action variable A(t). The reinforcement learning algorithm 112 may update the policy 114 for each specific time point, based on the received state variable S(t), reward variable R(t), and action variable A(t). The reinforcement learning algorithm 112 may enable the agent 110 to be trained in a right direction through appropriate update of the policy 114. The policy 114 of the agent 110 may be cyclically updated, and the cycle for updating the policy 114 may be updated for each repeated learning, and may be updated for each completion of an episode of the reinforcement learning, by performing repeated learning until an optimal value is found. Accordingly, more effective reinforcement learning may be performed by updating the policy 114 that is a system to generate the reward variable R(t) through the information obtained from the episode, not by a simple repetition, in the reinforcement learning.

In operation S700, the circuit simulation 122 may update the state variable S(t) to S(t+1) based on the action variable A(t). In detail, when the action variable A(t) is input to the circuit simulation 122, the circuit simulation 122 may update the state variable S(t) to the state variable S(t+1) by reflecting the input. The state variable S(t+1) that is output may become a new output value of the environment 120. The updated state variable S(t+1) is input to the circuit simulation 122, and thus, the output data O(t+1) corresponding thereto may be output.

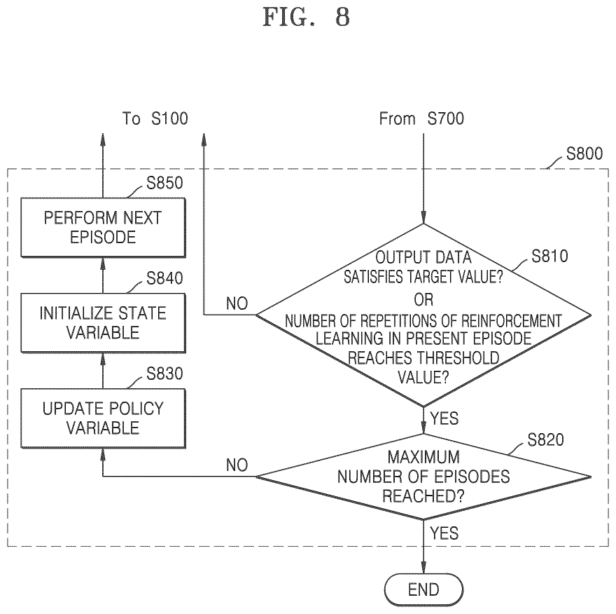

In operation S800, the reinforcement learning model 100 determines whether a termination condition is satisfied, and until the termination condition is satisfied, operations S100, S200, S300, S400, S500, S600, and S700 are repeated to perform the reinforcement learning. While repeatedly performing the reinforcement learning, the policy 114 of the agent 110 may be updated whenever a specific time point is reached. Accordingly, the agent 110 may find a more effectively optimized circuit design method. The specific time point for updating the policy 114 may be updated for each repetition of reinforcement learning, or whenever an episode of reinforcement learning is completed by performing the repeated learning until an optimal value is found. Furthermore, when a specific termination condition is satisfied, the reinforcement learning is terminated and an optimal state variable S(t) and the output data O(t) at that time are derived, thereby driving an optimal circuit design result. The termination condition may be set to be a case in which reinforcement learning is performed a certain number or more, or a case of training for a certain time or more. Furthermore, the termination condition may be set to a case when a target specification value or the maximum episode number is reached. A detailed description about the termination condition is presented later with reference to FIG. 8.

FIG. 7 is a flowchart of a method of estimating a variation of a circuit, in the method of designing a circuit based on reinforcement learning according to at least one embodiment.

As illustrated in FIG. 7, estimating a variation of a circuit (S300) may include operation S310 and operation S320. In detail, the flowchart of FIG. 7 shows an example of operation S300 of FIG. 6.

Referring to FIG. 7, in operation S310, variations of devices included in the circuit may be estimated. The variations of devices may include variations, such as performance, properties, yield, an output value, and the like. For example, when the device is a transistor, a variation that performance between transistor devices varies depending on a semiconductor process may occur. For example, a variation may occur in the threshold voltage of a transistor depending on various variations of the transistor. Pelgrom's Law, a formula that summarizes a relationship between a variation of the threshold voltage of a transistor and sizing, such as width, length, and the like, of the transistor, is presented in Equation 2.

$$Pelgrom ' s Law : {σ}_{VT} = \frac{{A}_{VT}}{\sqrt{2 WL}} \qquad [ Equation 2 ]$$

σ_{VT} denotes the standard deviation of a threshold voltage of a transistor, W denotes the channel width of a transistor, L denotes the channel length of a transistor, and A_{VT} is a constant affected by only a process and the like. A_{VT} may be constant with respect to devices identically designed in the same semiconductor process. For convenience of process, the channel length of a transistor may be constant, and the channel width of a transistor may be adjustable. Accordingly, the variation of a threshold voltage of a transistor may be mainly affected by the channel width of a transistor. Accordingly, as described below, by using the width of a transistor and Pelgrom's Law, the variation of a transistor may be estimated for the reward variable R(t).

In operation S320, based on the variations of devices, the variation of a circuit may be calculated. There may be various devices in a circuit, and performance of devices may be dependent on each other, but generally the performance of each device is independent, and the variation of each device is mostly a factor that is independently generated for each device. Thus, the variations of devices may be seen to be independent. As a variance of the sum of probability variables that are independent is the same as the sum of a variance of each probability variable, by using this, the above-described example, the variation of the threshold voltage of the overall transistor in the entire circuit may be calculated as shown in Equation 3 below.

$${σ}_{VT , total} = \sqrt{{\sum }_{k = 1}^{n} {σ}_{VT , k}^{2}} = \frac{{A}_{VT}}{\sqrt{2}} \sqrt{{\sum }_{k = 1}^{n} \frac{1}{{W}_{k}}} ( If , {A}_{VT} and L are equal ) \qquad [ Equation 3 ]$$

Accordingly, through this, the variation (or size of a variation) of the entire circuit may be estimated by using the width of each transistor. This is an example embodiment, and for other variations, in the independent case, the variation of the entire circuit may be estimated by using the sum of variances in the same manner.

As described above, the variation of a circuit is estimated by using the variation of each device, and reinforcement learning is performed by reflecting the estimated variation of a circuit to the reward variable R(t), so that an optimal design reflecting the variation may be obtained, and a circuit design with advantages in terms of accuracy and performance may be possible.

FIG. 8 is a flowchart of a method of determining whether a termination condition is satisfied, in the method of designing a circuit based on reinforcement learning, according to at least one embodiment.

As illustrated in FIG. 8, determining whether a termination condition is satisfied (S800) may include operations S810, S820, S830, S840, and S850. In detail, the flowchart of FIG. 8 shows an example of operation S800 of FIG. 6.

Referring to FIG. 8, in operation S810, when the output data O(t) satisfies a target value (Target Spec) or the number of repetitions of reinforcement learning in the corresponding episode reaches a set threshold value, the process may move to operation S820, and otherwise, to operation S100. This is to perform the next episode when one episode of reinforcement learning is completed by performing repeated learning until a series of a series of optimal values are found, and otherwise, to perform the repeated learning within the episode. One episode may be terminated when the number of repetitions of reinforcement learning reaches a threshold value that is a preset maximum repetition number, or when the output data O(t) satisfies a target value that is a target specification value. This is an example, reinforcement learning may be performed by using a termination condition of an episode that is commonly used in the reinforcement learning.

In operation S820, when the maximum number of episodes is reached, the reinforcement learning is terminated, and otherwise, the process moves to operation S830. Because it is not possible or practical to limitlessly perform the reinforcement learning, the maximum number of episodes to be collected as a termination condition is set, and when the condition is satisfied, the reinforcement learning may be terminated and an optimal design may be obtained based on the generated episode. When the maximum number of episodes is not reached, the policy 114 of reinforcement learning may be updated based on the information obtained through the reinforcement learning in the episode, and a new episode may be performed.

In operation S830, a policy variable may be updated (Policy Update). As described above with reference to FIG. 6, more effective reinforcement learning may be performed by updating the policy 114 that is a system to generate the reward variable R(t) through the information obtained from the episode, not by a simple repetition, in the reinforcement learning.

In operation S840, the state variable S(t) may be initialized. Accordingly, the state in the previous episode is reset, and a new episode may be performed. There may be a case in which reset is not performed, and only a partial state may be reset. The value to be reset may consist of deterministic values or stochastic values. The value to be reset may be selected from among a plurality of values.

In operation S850, the next episode may be performed. The record of a previous episode may be stored, and repeated learning in a new episode may start. Through the present operation, while repeated learning is performed, episodes may be sequentially generated.

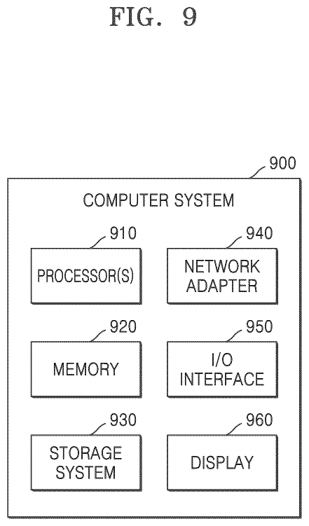

FIG. 9 is a block diagram of a computer system 900 according to at least one embodiment.

In some embodiments, the computer system 900 of FIG. 9 may perform the method of designing a circuit based on reinforcement learning described above with reference to the drawings, and may be referred to as a circuit design system, a reinforcement learning system, or the like. For example, the computer system 900 may implement a reinforcement learning model (for example, FIGS. 1 to 3). In at least one embodiment, the computer system 900 may be implemented in (and/or conjunction with) a circuit manufacturing apparatus.

The computer system 900 may refer to a certain system including general purpose or special purpose computing system. For example, the computer system 900 may include a personal computer, a server computer, a laptop computer, a home appliance product, and the like. As illustrated in FIG. 9, the computer system 900 may include at least one processor 910, a memory 920, a storage system 930, a network adaptor 940, an input/output (I/O) interface 950, and a display 960.

The at least one processor 910 may perform a program module including instructions to be executable on a computer system. The program module may include routines, programs, objects, components, logics, data structures, and the like, to perform a specific task or implement a specific virtual data type. The memory 920 may include a computer system readable medium of a volatile memory, such as random access memory (RAM). The at least one processor 910 may access the memory 920, and execute instructions loaded on the memory 920. The storage system 930 may store information in a non-volatile manner, and in some embodiments, include at least one program product including a program module configured to perform reinforcement learning training for circuit design, which is described above with reference to the drawings. The program may include, as a non-limiting example, an operating system, at least one application, other program modules, and program data.

The network adaptor 940 may provide connection to a local area network (LAN), a wide area network (WAN), a public network (e.g., the Internet), and/or the like. The input/output interface 950 may provide a communication channel to peripheral devices, such as a keyboard, a pointing device, an audio system, and the like. The display 960 may output various information for a user to check.

In some embodiments, the method of designing a circuit based on reinforcement learning described above with reference to the drawings may be implemented as a computer program product. The computer program product may include a non-transitory computer readable medium (or storage medium) including computer readable program instructions for the at least one processor 910 to perform image processing and/or training of models. The computer readable program instructions may include, as a non-limiting example, assembler instructions, instruction set architecture (ISA) instructions, machine instructions, machine-dependent instructions, micro code, firmware instructions, state setting data, or source code or object code written in at least one programming language.

The computer readable program medium may include any type of medium capable of non-transitively holding and storing instructions executed by the at least one processor 910 or any instruction executable device. The computer readable program medium may include an electronic storage device, a magnetic storage device, an optical storage device, an electromagnetic storage device, a semiconductor storage device, or any combination thereof, but is not limited thereto. For example, the computer readable program medium may include machine-encoded devices, such as a portable computer diskette, a hard disk, RAM, read-only memory (ROM), electrically erasable read only memory (EEPROM), flash memory, static random access memory (SRAM), CD, DVD, Memory Stick, a floppy disk, and punch cards, or any combination thereof.

After training, the reinforcement learning model may be used to confirm and/or deny potential layouts. For example, the reinforcement learning model may be applied in a control module for a circuit processing apparatus, such that the reinforcement learning model approves or rejects a variation in the state variable S(t). For example, when the reinforcement learning model approves the state variable S(t), based on the results of the reinforcement learning model, a control module may direct the circuit processing apparatus to produce the circuit; and/or when the control module rejects the layout, the control module may direct the circuit processing apparatus to pause production and/or may provide corrections to the layout and produce the circuit based on the corrected layout. According to some embodiments, the control model may further provide (or display) the characteristic yielding the process error, and may provide for the correction of and retesting of a layout based on an inputted correction or modification. In at least one example, a change detected in the circuit processing apparatus may be applied, in real-time, to reinforcement learning model, and the viability of the circuit being processed can be estimated, and if the likelihood of viability is below a threshold the circuit processing apparatus may be paused and/or the circuit may be discarded and/or reprocessed.

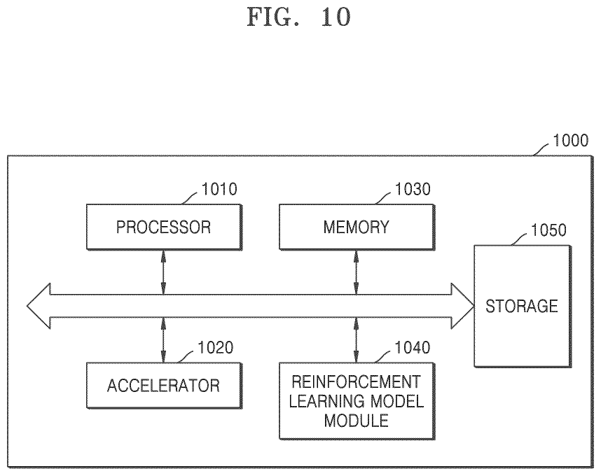

FIG. 10 is a block diagram of a system 1000 according to at least one embodiment.

In some embodiments, measurement according to at least one embodiment structure may be performed in the system 1000. The system 1000 may implement a reinforcement learning model (for example, FIGS. 1 to 3).

As illustrated in FIG. 10, the system 1000 may include at least one processor 1010, an accelerator 1020, a memory 1030, a reinforcement learning model module 1040, a storage 1050, and a bus 1060. Although FIG. 10 illustrates one processor 1010 only, more processors may be provided. The at least one processor 1010, the memory 1030, the reinforcement learning model module 1040, and the storage 1050 may mutually communicate via the bus 1060. In some embodiments, the at least one processor 1010, the memory 1030, the accelerator 1020, and the reinforcement learning model module 1040 may be included in one semiconductor chip. Furthermore, in some embodiments, at least two of the at least one processor 1010, the memory 1030, the accelerator 1020, and the reinforcement learning model module 1040 may be included in each of two or more semiconductor chips mounted on a board.

The at least one processor 1010 may execute a series of instructions. For example, the at least one processor 1010 may execute the instructions stored in the memory 1030 or the storage 1050. Furthermore, the at least one processor 1010 may load the instructions from the memory 1030 or the storage 1050 on an internal memory, and execute the loaded instructions. In some embodiments, the at least one processor 1010 may perform at least some of the operations described above with reference to the drawings, by executing the instructions. For example, the at least one processor 1010 may execute an operating system by executing the instructions stored in the memory 1030, and execute applications executed on the operating system. In some embodiments, the at least one processor 1010 may instruct, by executing the instructions, the accelerator 1020 and/or the reinforcement learning model module 1040 to do a task, and obtain a result of task from the accelerator 1020 and/or the reinforcement learning model module 1040. In some embodiments, the at least one processor 1010 may include an application specific instruction set processor (ASIP) that is customized for a specific purpose, and support a dedicated instruction set.

The accelerator 1020 may be designed to perform a predefined operation at high speed. For example, the accelerator 1020 may load data stored in the memory 1030 and/or the storage 1050, and store data generated by processing the loaded data, in the memory 1030 and the storage 1050. In some embodiments, the accelerator 1020 may perform, at high speed, at some of the operations described above with reference to the drawings.

The memory 1030, which is a non-transitory storage device, may be accessed by the at least one processor 1010 via the bus 1060. In some embodiments, the memory 1030 may include volatile memory, such as dynamic random access memory (DRAM), static random access memory (SRAM), and the like, and non-volatile memory, such as flash memory, resistive random access memory (RRAM), and the like. In some embodiments, the memory 1030 may store instructions and data to perform some of the operations described above with reference to the drawings.

Functional elements such as those including “unit”, “ . . . er/or”, “module”, “logic”, etc., described in the specification mean elements that process at least one function or operation, and may be implemented as processing circuitry such as hardware, software, or a combination of hardware and software, unless expressly indicated otherwise. For example, the processing circuitry more specifically may include, but is not limited to, electrical components such as at least one of transistors, resistors, capacitors, etc.,/or electronic circuits including said components, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. However, the meaning of a module is not limited to software or hardware. The module may be configured to be present in an addressable storage medium, or configured to execute one or more processors. Accordingly, as an example, the module may include constituent elements, such as software constituent elements, object-oriented software constituent elements, class constituent elements, and task constituent elements, and processes, functions, attributes, procedures, sub-routines, segments of program code, drivers, firmware, microcode, circuit, data, database, data structures, tables, arrays, and variables. A function provided by the constituent elements and the modules may be obtained by combining less constituent elements and modules or further separating the constituent elements and the modules into additional constituent elements and modules.

The reinforcement learning model module 1040 may control a skew and duty error rate based on the reinforcement learning. In the reinforcement learning model module 1040, the agent 110 may be trained to perform action to maximize a reward in the environment. The reinforcement learning model module 1040 may store, by using the at least one processor 1010, data needed for the simulation of a reinforcement learning model. The data needed for simulation may be stored in the storage 1050. The reinforcement learning model module 1040 may optimize, by performing reinforcement learning, the variation-sensitive properties of a circuit in a circuit design method, and thus, a circuit design with improved accuracy and performance may be obtained.

The storage 1050, which is a non-transitory storage device, may not lose stored data even when power supply is cut off. For example, the storage 1050 may include a semiconductor memory device such as flash memory, or a certain storage medium, such as a magnetic disc, an optical disc, and the like. In some embodiments, the storage 1050 may store instructions, programs, and/or data to perform at least some of the operations described above with reference to the drawings.

As described above, by including variation-aware data in the reward, the result of the reinforcement learning model converges to a variation-aware optimal point (or sizing). As such, accurate and optimal sizing may be quickly derived by correcting the single simulation result and/or policy, instead of re-running and/or retraining the simulation (e.g., 122 of FIG. 3) which may require a longer time and/or greater computational resources.

While the disclosure has been particularly shown and described with reference to preferred embodiments using specific terminologies, the embodiments and terminologies should be considered in descriptive sense only and not for purposes of limitation. Therefore, it will be understood by those of ordinary skill in the art that various changes in form and details may be made therein without departing from the spirit and scope of the disclosure as defined by the following claims.

What is claimed is:

1. A method of designing a circuit based on reinforcement learning, the method comprising:
generating output data by performing a simulation of the circuit based on a state variable of the reinforcement learning;
determining a reward variable of the reinforcement learning based on the output data;
obtaining an action variable, from a reinforcement learning agent, based on the state variable and the reward variable;
training the reinforcement learning agent based on the state variable, the reward variable, and the action variable; and
updating the state variable based on the action variable,
wherein the determining of the reward variable includes
estimating a variation of the circuit based on the state variable, and
determining the reward variable based on the estimated variation.

2. The method of claim 1, wherein the estimating the variation of the circuit comprises:
estimating variations of devices included in the circuit, and
determining the variation of the circuit based on the estimated variations of the devices.

3. The method of claim 2, wherein
the estimating the variations of the devices comprises estimating a variance of threshold voltages of the devices based on a size of each of the devices, and
the determining the variation of the circuit comprises determining a variance of a threshold voltage of the circuit based on a sum the variances of the threshold voltages of the devices.

4. The method of claim 3, wherein
the determining the variation of the circuit further comprises determining a standard deviation (σ) of the threshold voltage of the circuit based on the variance of the threshold voltage of the circuit, and
the determining the reward variable comprises determining the reward variable based on a multiple of a weighted sum of at least one value indicating performance of the circuit and the standard deviation (σ) of the threshold voltage of the circuit.

5. The method of claim 1, wherein the obtaining the state variable, the obtaining the output data, the determining the reward variable, the obtaining of the action variable, the training of the reinforcement learning agent, and the updating of the state variable are repeatedly performed until a number of episodes of the reinforcement learning reaches a set maximum number of the episodes, and
when the output data satisfies a target value or a number of repetitions of reinforcement learning in the episode reaches a set threshold value, the episode is terminated and a next episode is performed.

6. The method of claim 5, wherein the training of the reinforcement learning agent comprises updating a policy of the reinforcement learning and initializing the state variable when the episode is terminated and the next episode is performed.

7. The method of claim 1, wherein the state variable has a value defining a size of a device included in the circuit.

8. A system for designing a circuit based on reinforcement learning, the system comprising:
a non-transitory storage medium storing instructions to execute a process of performing the reinforcement learning; and
at least one processor configured to, by executing the instructions
obtain output data by performing a simulation based on a state variable of the reinforcement learning;
determine a reward variable of the reinforcement learning based on the output data;
obtain an action variable from a reinforcement learning agent based on the state variable and the reward variable;
train the reinforcement learning agent based on the state variable, the reward variable, and the action variable; and
update the state variable based on the action variable, and
wherein the determining of the reward variable includes
estimating a variation of a circuit based on the state variable; and
determining the reward variable based on the estimated variation.

9. The system of claim 8, wherein the estimating the variation of the circuit comprises:
estimating variations of devices included in the circuit, and
determining a variation of the circuit based on the estimated variations of the devices.

10. The system of claim 9, wherein
the estimating the variations of the devices comprises estimating a variance of threshold voltages of the devices based on a size of each of the devices, and
the determining the variation of the circuit comprises determining a variance of a threshold voltage of the circuit based on a sum of the variances of the threshold voltages of the devices, and determining a standard deviation (o) of a threshold voltage of the circuit from the variance of the threshold voltage of the circuit.

11. The system of claim 10, wherein the determining the reward variable comprises determining the reward variable based on a multiple of a weighted sum of at least one value indicating performance of the circuit and the standard deviation of (o) the threshold voltage of the circuit.

12. The system of claim 8, wherein the obtaining the state variable, the obtaining the output data, the determining the reward variable, the obtaining the action variable, the training of the reinforcement learning agent, and the updating of the state variable are repeatedly performed until a number of episodes of the reinforcement learning reaches a set maximum number of the episodes, and
in response to the output data satisfying a target value or a number of repetitions of reinforcement learning in the episode reaching a set threshold value, the episode is terminated and a next episode is performed.

13. The system of claim 12, wherein the training of the reinforcement learning agent comprises updating a policy of the reinforcement learning and initializing the state variable in response to the episode being terminated and the next episode being performed.

14. The system of claim 8, wherein the state variable has a value for defining a size of a device included in the circuit.

15. A non-transitory storage medium storing instructions, which when executed by at least one processor, cause the at least one processor to execute a process of performing reinforcement learning, the process of performing the reinforcement learning comprises:
generating output data by performing a simulation based on a state variable of the reinforcement learning;
determining a reward variable of the reinforcement learning based on the output data;
obtaining an action variable from a reinforcement learning agent based on the state variable and the reward variable;
training the reinforcement learning agent based on the state variable, the reward variable, and the action variable; and
updating the state variable based on the action variable,
wherein the determining of the reward variable comprises
estimating a variation of a circuit based on the state variable, and
determining the reward variable based on the estimated variation.

16. The non-transitory storage medium of claim 15, wherein the estimating the variation of a circuit comprises:
estimating variations of devices included in the circuit; and
determining a variation of the circuit based on the estimated variations of the devices.

17. The non-transitory storage medium of claim 16, wherein
the estimating the variations of the devices comprises estimating a variance of a threshold voltage of each of the devices based on a size of each of the devices, and
determining the variation of the circuit comprises determining a variance of a threshold voltage of the circuit based on a sum of variances of the threshold voltages of the devices, and determining a standard deviation (o) of a threshold voltage of the circuit from the variance of the threshold voltage of the circuit.

18. The non-transitory storage medium of claim 17, wherein the determining of the reward variable comprises determining the reward variable based on a multiple of a weighted sum of at least one value indicating performance of the circuit and the standard deviation of the threshold voltage of the circuit.

19. The non-transitory storage medium of claim 15, wherein the obtaining the state variable, the obtaining of the output data, the determining of the reward variable, the obtaining of the action variable, the training of the reinforcement learning agent and the updating of the state variable are repeatedly performed until a number of episodes of the reinforcement learning reaches a set maximum number of the episodes, and
in response to the output data satisfying a target value or a number of repetitions of reinforcement learning in the episode reaching a set threshold value, the episode is terminated and a next episode is performed.

20. The non-transitory storage medium of claim 15, wherein the state variable has a value for defining a size of a device included in the circuit.
